(19) United States
(12) Patent Application Publication
(10) Pub. No.: US 2005/0072625 A1
(43) Pub. Date: Apr. 7, 2005

(54) Acoustic diffusers for acoustic field uniformity

(76) Inventor: Kurt K. Christenson, Minnetonka, MN (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 10/939,245

(22) Filed: Sep. 10, 2004

Related U.S. Application Data
(60) Provisional application No. 60/501,969, filed on Sep. 11, 2003.

(51) Int. Cl. H03G 3/00

(52) U.S. Cl. 181/210

(57) ABSTRACT

Apparatuses and methods for processing semiconductor wafers. In one embodiment, an apparatus includes an immersion processing tank in which one or more wafers are positioned in a processing liquid during a treatment, at least one sound source that is acoustically coupled to the processing liquid and that produces a sound field in the processing liquid contained in the processing tank during a treatment, and a sound diffusing system comprising a plurality of sound diffusing elements positioned in a manner effective to diffuse sound energy transferred from the source to the processing liquid. In another embodiment, the sound diffusing system includes at least one directionally phase modulating element positioned in a manner effective to reduce interference of sound energy in the processing liquid. Related methods are also described.

### CROSS-REFERENCE TO RELATED APPLICATIONS

The present non-provisional Patent Application claims the benefit of priority under 35 USC 119 from commonly owned U.S. Provisional Patent Application having Ser. No. 60/501,969, filed on Sep. 11, 2003, in the name of Christenson, and titled ACOUSTIC DIFFUSERS FOR ACOUSTIC FIELD UNIFORMITY, which Patent Application is incorporated herein by reference in its entirety.

### FIELD OF THE INVENTION

The field of this invention relates to microelectronic processing systems and methods for treating wafers immersed in a process liquid in the presence of acoustic energy, and more particularly, this invention relates to such systems and methods in which a sound diffusing system is used to improve the uniformity of the sound field established in the process liquid.

### BACKGROUND OF THE INVENTION

Acoustic energy, such as megasonic energy in the megahertz frequency range, is used in the microelectronics industry in the course of manufacturing microelectronic devices. In a representative system, a source of megasonic energy is coupled to a process chamber. Many semiconductor processing systems, for example, having megasonic capabilities are known. The source can be external to the process chamber or internal. Megasonic energy is often used in the course of cleaning and rinsing treatments. For instance, U.S. Pat. Nos. 4,869,278; 5,017,236; 5,365,960; and 6,367,493 describe processes that use megasonic energy. See also assignee's U.S. provisional application titled “Frequency Sweeping for Acoustic Field Uniformity,” filed Sep. 11, 2003 by Christenson et al., having Ser. No. 60/501,956, and having Attorney Docket No. FSI0120/P1, the disclosure of which is incorporated herein by reference in its entirety.

Megasonic energy and waves can be used for a variety of reasons, including cleaning and removing particles from the surface of semiconductor wafers during wafer processing into devices and integrated circuits. Megasonic energy generally refers to high frequency acoustic energy including frequencies in the range of from about 0.5 MHZ to about 2 MHZ or higher.

Megasonic cleaning is used at many stages in the fabrication process for removing particles, photoresist, dewaxing and degreasing using different solvents and stripping solutions. It has also been shown that megasonic energy can aid in the removal of particulates that are adhered to the wafer surface. The primary advantages of using megasonic cleaning include that it can provide superior cleanliness (such as with respect to particulates and the like) and simultaneously clean both sides of wafers being processed, thereby requiring less chemical action.

As the microelectronics industry moves to stricter standards and smaller device features, field uniformity becomes more important. Smaller features tend to be more vulnerable to acoustic damage than some larger features. Cleaning performance also becomes more critical inasmuch as particle contamination tends to be much less tolerable as device features become smaller.

U.S. Pat. No. 4,869,278 describes a megasonic processing system containing an acoustic diffusing feature. However, only a single, diffusing lens feature is shown and it is generally symmetric, e.g., semi-cylindrical. Sound may be diffused, but the resulting sound field still would suffer from unduly large maxima and minima interference effects. In short, the resultant interference pattern generated in the tank is different than it would be in the absence of the diffusing element, but would still be present to an undue degree. Also, wafer portions near the lens (such as in the middle of the tank) will see a louder sound field than portions far from the lens (such as at a tank wall or the like).

Accordingly, there is still a need to generate spatially and temporally uniform sound fields (minimized temporal variations) in a processing tank and especially to dampen the peak-to-peak height between field maxima and minima while still maintaining sufficient field strength to accomplish the desired treatment.

### SUMMARY OF THE INVENTION

The present invention involves systems and methods in which a sound diffusing system is used to help diffuse the sound field established within a processing liquid during the course of a treatment in which one or more wafers are immersed in the sonified liquid. The sound diffusing system helps to minimize the range of intensities among sound waves generated in the processing fluid. Greater uniformity can save in the cost of chemical cleaners, can provide superior cleanliness, and can reduce the potential to damage features on the wafers by reducing the acoustic intensity at the field maxima.

In one aspect, then, the present invention relates to using a sound diffusing system including a plurality of sound diffusing elements that cooperatively function to help sonify the processing volume more uniformly, e.g., with a narrower distribution of sound wave intensities. The individual diffusing elements may be discrete from one another or may be integrally formed. If integrally formed on a substrate or otherwise, the sound diffusing system may include diffusing elements that may be formed in a material as protuberances and/or depressions. In many embodiments, the sound diffusing system is provided by one or more physical structures positioned in the acoustic pathway between the acoustic energy source and the wafer(s) being processed to help sonify the processing volume occupied by the wafer(s) more uniformly. Such physical structures desirably dampen field maxima and minima while still allowing sufficient acoustic energy to pass to achieve desired field strength.

In another aspect, the present invention relates to individual diffusing elements that constitute all or a portion of a sonic diffusing system. In general, the diffuser elements of the present invention allow sound energy to pass, but preferably diffuse the sound so that maxima and minima in field variation are dramatically dampened. The effect is very analogous to the way frosted glass diffuses light passing through it. A sonic diffusing element preferably comprises at least one surface feature that helps control refraction, diffraction, phase modulation, and/or phase shifting of sound energy. Such diffusing characteristics of such elements may depend upon physical structure, and/or other factors. For example, a sonic diffuser may include one or more of topographic features (e.g., surface texture), surface curvature features, protuberances, depressions, sonic velocity controlling features, diffraction elements such perforations or the like, combinations of these, or the like to help more uniformly sonify the process tank.

According to another aspect of the present invention, an apparatus for immersion processing wafers includes (1) an immersion processing tank in which one or more wafers are positioned in a processing liquid during a treatment, (2) at least one sound source that is acoustically coupled to the processing liquid and that produces a sound field in the processing liquid contained in the processing tank during a treatment, and (3) a sound diffusing system comprising a plurality of sound diffusing elements positioned in a manner effective to diffuse sound energy transferred from the source to the processing liquid.

According to another aspect of the present invention, an apparatus for immersion processing wafers includes (1) an immersion processing tank in which one or more wafers are positioned in a processing liquid during a treatment, (2) at least one sound source that produces a sound field in the processing liquid contained in the processing tank, and (3) a sound diffusing system comprising at least one directionally phase modulating element positioned in a manner effective to reduce interference of sound energy in the processing liquid.

According to another aspect of the present invention, a method of providing a sound field in a processing liquid contained in an immersion processing tank includes the steps of (1) providing a sound field in the processing liquid and (2) directionally phase modulating the sound field by using a sound diffusing system including a plurality of sound diffusing elements.

According to another aspect of the present invention, a method of providing a sound field in a processing liquid contained in an immersion processing tank includes the steps of (1) determining information indicative of a sound field variation in the processing liquid and (2) using said information to provide a sonic diffuser system to be used to diffuse sound energy in the processing liquid during a wafer treatment process.

### BRIEF DESCRIPTION OF THE DRAWINGS

The understanding of the above mentioned and other advantages of the present invention, and the manner of attaining them, and the invention itself can be facilitated by reference to the following description of the exemplary embodiments of the invention taken in conjunction with the accompanying drawings, wherein:

FIG. 1 illustrates a schematic, side, cross-sectional view of an immersion processing tank with acoustic capability and being useful in the practice of the present invention.

FIG. 2 illustrates a profile of a megasonic field strength across a width of a megasonic tank without a sound diffusing system according to the present invention.

FIG. 3 shows a perspective view of a sound diffusing system according to the present invention having a periodic array of openings.

FIG. 4 shows a perspective view of another sound diffusing system according to the present invention having a periodic array of openings/perforations.

FIG. 5a shows a perspective view of another sound diffusing system according to the present invention having a periodic array of openings/perforations.

FIG. 5b shows a perspective cross-section view of a portion of the sound diffusing system of FIG. 5a.

FIG. 6 illustrates a diffusing element according to the present invention in the form of a diverging lens and how this element modulates sound energy passing through it.

FIG. 7 illustrates a top plan view of an exemplary sound diffusion system according to the present invention incorporating an array of convex hemispherical diffusing elements.

FIG. 8 illustrates a top plan view of an exemplary sound diffusion system according to the present invention incorporating an array of concave hemispherical diffusing elements.

FIG. 9 shows a top plan view of an exemplary sound diffusion system according to the present invention incorporating an array of hemispherical diffusing elements in which the elements are of differing sizes and are arranged aperiodically.

FIG. 10 shows that a sound diffusion system according to the present invention incorporating an array of diffusing elements in which the elements are of differing sizes and shapes and are arranged aperiodically can be produced by randomly distributing diffusing elements on a substrate.

FIG. 11 shows a top, plan view of a sound diffusion system according to the present invention incorporating an array of relatively long, cylinder-based, rib-like elements.

FIG. 12 shows a perspective, cross-sectional view of the array in FIG. 11.

FIG. 13 shows a top, plan view of a sound diffusion system according to the present invention incorporating an aperiodic array of long, cylinder-based, rib-shaped elements whose widths are nonconstant.

FIG. 14 shows a perspective, cross-sectional view of the array in FIG. 13.

FIGS. 15a-d shows side, cross-sectional views of alternative shapes for an array of sound diffusing elements according to the present invention.

FIG. 16 shows a schematic, side view of portion of an apparatus for processing wafers including a sound diffusing system according to the present invention in which array sections of the sound diffusing system are arranged in a peaked fashion.

FIG. 17 shows a schematic, perspective view of a sound diffusing system according to the present invention including array sections that are arranged in a peaked fashion.

FIG. 18 shows another schematic, perspective view of the sound diffusing system in FIG. 17, further showing how a wafer may be positioned with respect to the sound diffusing system.

FIG. 19 shows a schematic, cross-sectional view of part of the sound diffusing system in FIG. 17.

FIG. 20(a) shows a schematic, side view of an apparatus for processing wafers including a polymer window to help minimize tank volume.

FIG. 20(b) shows a schematic, side view of an apparatus for processing wafers including a polymer window to help drain the tank fast.

FIG. 21(a) shows a schematic, side view of an apparatus for processing wafers including a sound diffusing system according to the present invention in which the window and sound diffusing system are combined.

FIG. 21(b) shows a schematic, side view of an apparatus for processing wafers including a sound diffusing system according to the present invention in which the crystal support plate and sound diffusing system are combined.

FIG. 22 shows a graph of sound intensity with respect to position in a megasonic processing tank with a quartz window at some point in time, wherein the graph includes data with and without a sound diffusing system according to the present invention.

### DETAILED DESCRIPTION OF THE INVENTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

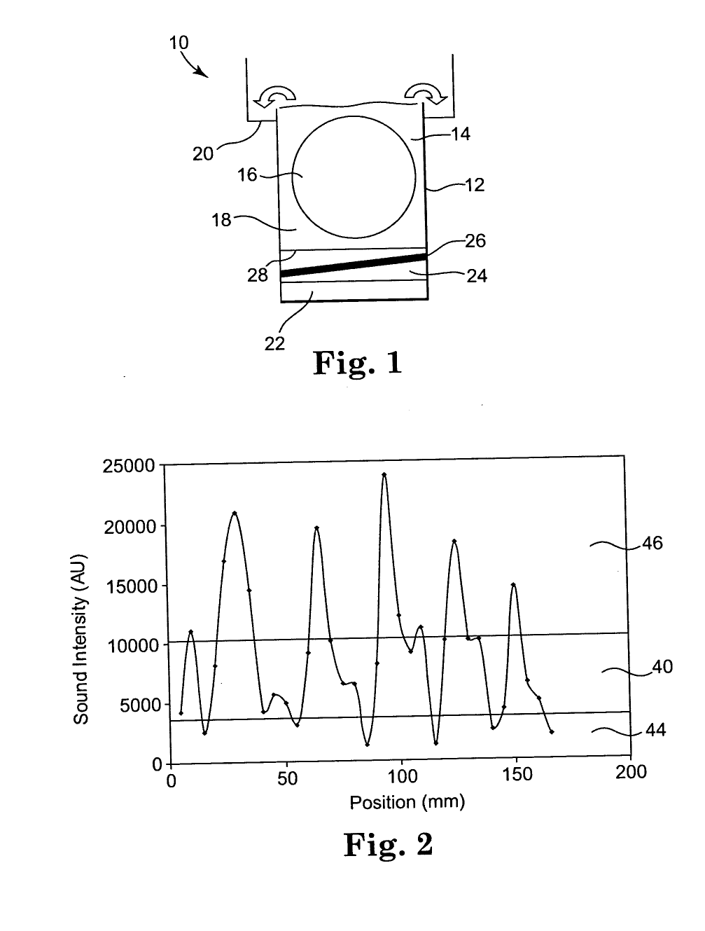

The principles of the present invention may be practiced in any kind of equipment (e.g., single wafer tools or batch processing tools) in which one or more wafers are immersed in a sonified bath during the course of a treatment. One suitable and representative processing tank 10 with acoustic, e.g., megasonic, capabilities of the type used in a wet bench tool (such as the MAGELLAN® system commercially available from FSI International, Inc., Chaska, Minn.) is shown schematically in cross-section in FIG. 1. Tank 10 may be used to treat wafer(s) either singly or in batches. Tank 10 generally includes a housing 12 defining a process chamber 14 in which one or more wafers 16 are immersed in a cascading flow of process liquid 18. Liquid 18 may be introduced into process chamber 14 through one or more entry ports (not shown) located generally toward the bottom of process chamber 14. Liquid 18 exits process chamber 14 by cascadingly overflowing into overflow weir 20 generally at the top of process chamber 14.

Sound source 22 produces a sound field in the processing liquid 18 contained in the processing chamber 14 during a treatment. In this example, the acoustic energy source 22 is external to the process chamber 14. In typical embodiments, the acoustic energy source 22 incorporates a resonant structure (not shown) that generally comprises (from bottom to top) piezoelectric crystals bonded to a metal or ceramic support plate or the like. The acoustic energy source 22 is acoustically coupled to the contents inside the processing chamber 14 by a coupling fluid 24 such as water or the like. A quartz window 26 provides a pathway for acoustic energy to pass from the coupling fluid 24 into the process chamber 14.

The coupling fluid 24 is used to isolate the acoustic energy source 22 from the processing liquid 18 for a number of possible reasons such as (a) to prevent attack on the acoustic energy source 22 by the process liquid 18; (b) to prevent contamination of the processing liquid 18 by the acoustic energy source 22; and/or (c) to maintain a temperature differential between the coupling water 24 and the process liquid 18. The temperature of the coupling liquid 24 can be reduced to limit the temperature of the acoustic energy source 22.

Ideally, the quartz window 26 would be parallel to the transducer (not shown) of acoustic energy source 22 and spaced such that the standing waves in the coupling liquid 24 enhance transmission into the processing liquid 18. Achieving this would require holding dimensional tolerances to a fraction of the wavelength of the acoustic energy, e.g., a fraction of the 1.5 mm wavelength of 975 kHz megasonic energy in DI. This can be difficult to achieve practically. In reality, the quartz window 26 is often deliberately tilted to create a rapid oscillation in the transmission pattern that hopefully “smoothes out” by the time the sound reaches the wafer(s) 16. This smoothening is unlikely to occur with the small plate-to-wafer spacing on certain tanks.

The present invention appreciates that, even if the average field intensity in the processing fluid 18 is within a desired operating range, the field throughout the processing fluid 18 and/or at localized regions may vary between maxima and minima outside the desired operating range. If the field is too weak, process performance can suffer. If the field is too strong, the acoustic energy can physically damage device features. The field varies both spatially and temporally. Thus, one locale of the processing fluid may see a different time averaged field strength than another locale. For example, FIG. 2 shows a plot of the megasonic field strength across a width of a particular processing chamber containing a processing fluid in a wet bench tool. FIG. 2 shows the desired sound field intensities associated with a desired cleaning regime 40, a non-cleaning regime 44 in which field intensity is too low, and a damage regime 46 in which field intensity is too high.

The present invention appreciates that there are multiple sources of field non-uniformity that can lead to undesired spatial and temporal non-uniformities of the sonified process liquid. Representative sources of non-uniformity include (a) variations in the thickness of the quartz window, (b) variations in the output of the acoustic energy source, (c) change in distance between the acoustic energy source and the quartz window, (d) reflections at the quartz window, which is not fully transparent to acoustic energy (a quartz window may reflect 40% of incident megasonic energy and these reflections tend to produce a standing wave between the quartz and the transducer whose wave pattern can be projected into the processing fluid), and/or (e) constructive and destructive interference effects from sound waves interacting in the process tank. With respect to variations in the thickness of the quartz window, if the window is not parallel sided, for example, the acoustic path length (APL) through the quartz can vary with position. As the transmission varies with variance of the APL, the transmission of sound to the processing liquid can change. This can lead to non-uniformities in the acoustic field in the region around the wafers (note: the highest theoretical transmission through quartz generally occurs when the thickness is a multiple of ½λ (about 2.9 mm for quartz at 975 kHz)).

Temporal variations can occur due to interference between two sound fields of differing frequency as treated in the assignee's application titled “Frequency Sweeping for Acoustic Field Uniformity” (Ser. No. 60/501,956; Attorney Docket No. FSI0120/P1). Temporal variations can also arise from self-focusing of sound. The speed of sound in regions of water with high intensity sound is lower than that of water in low intensity regions. Accordingly, a region that further concentrates sound can be created.

Regardless of what source(s) contribute to field variation, it is apparent that the megasonic field generated in the process tank can fluctuate locally, tank-wide, and/or temporally more than is desired. Yet, in carrying out a particular treatment, the acoustic field strength established in the process fluid is desirably strong enough to facilitate treatment. The field is also desirably spatially and temporally uniform.

In the practice of the present invention, and referring again to FIG. 1, uniformity of the sound field can be improved by using a sound diffusing system 28 that helps to minimize the range of intensities among sound waves generated in the processing fluid. Greater uniformity can save in the cost of chemical cleaners, can provide superior cleanliness, and can reduce the potential to damage features on the wafers by reducing the acoustic intensity at the field maxima.

As shown in FIG. 1, sound diffusing system 28 is positioned within processing liquid 18 between wafer(s) 16 and the underlying quartz window 26. However, sound diffusing system 28 may be positioned in any manner to help diffuse the sound field established in processing liquid 18. For example, sound diffusing system 28 could be positioned in the coupling fluid 24, positioned proximal to inside or outside face(s) of the tank window, and/or positioned inside the processing tank. Alternatively, sound diffusing system 28 could be integrally formed with other tank features such as quartz window 26.

Sound diffusing system 28 desirably is formed from one or more materials that are at least partially transparent to acoustic energy. If placed inside the processing tank, the material should also be relatively inert to processing chemicals to be used in the tank. Examples of such materials include fluoropolymers (such as PTFE, PFA or PVDF), and polymers such as high density polypropylene (HDPE), polypropylene, combinations of these, and the like. A particularly preferred material is HDPE as this material is easily molded and is highly transmissive with respect to megasonic energy and is resistant to a wide range of chemicals used in the course of fabricating microelectronic devices.

Sound diffusing system 28 preferably includes a plurality of diffusing elements (not shown in FIG. 1, but further discussed in the context of various embodiments of sound diffusing systems as illustrated in the other Figures) having shape(s) and size(s) effective for diffusing acoustic energy and to help reduce interference effects in the processing fluid. The diffusing elements may comprise any size and shape to accomplish these objectives. Diffusing elements may comprise raised and/or recessed surface regions or features and may comprise ribs, channels, apertures, buttons, etc., and/or combinations thereof.

The physical structure and size of the elements constituting any such sound diffusing system may be the same or may differ among two or more of such elements. For instance, FIGS. 3-8, and 11-12 show illustrative embodiments of sound diffusing systems in which the size, shape, and physical spacing of diffusing elements is uniform. In other embodiments, the physical size, shape, and/or spacing of elements may vary. Individual elements can abut each other and/or be spaced apart. The elements may be arranged regularly, randomly, parallel, nonparallel, in a repeating pattern, or otherwise. The nonuniformity with respect to size, shape, and/or spacing is preferred, as it tends to provide a tighter distribution of sound wave intensities.

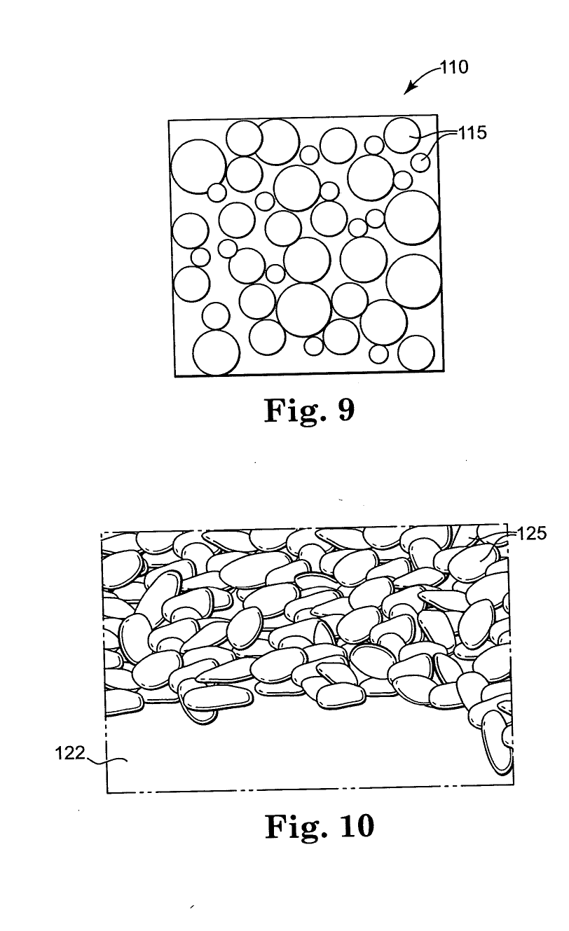

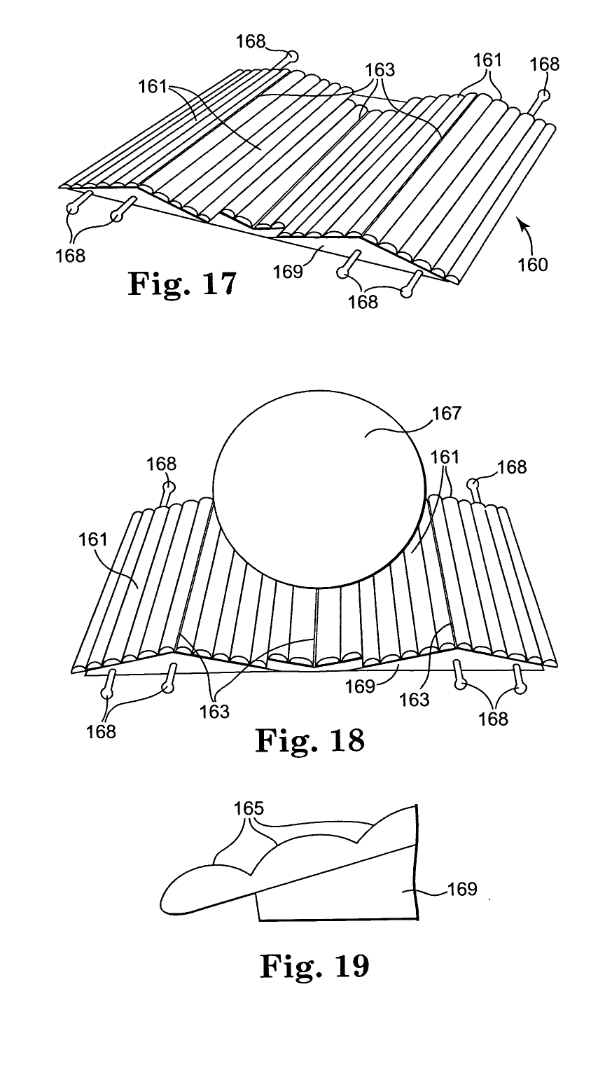

While not wishing to be bound by theory, it is believed that this advantage results because the diffusing features, having different spacings, tend to modulate wave patterns less consistently than an array of uniform diffusing features. This resultant phase shifting reduces the tendency of the wave patterns to constructively or destructively interfere, hence dampening field maxima and minima. In other words, it is believed that using diffuser elements having varying size, spacing, and/or shape can minimize the formation of standing waves in a processing tank or the like. Embodiments of the sound diffusing systems incorporating such nonuniformity are shown in FIGS. 9, 10, 13, 14, 15a, 15b, 15c, 15d, and 17-19.

Sound diffusion systems of the invention may incorporate diffraction grating features to help control sonification of the processing liquid, e.g., to control interference effects. In representative embodiments, a diffraction grating comprises one or more perforations or the like for diffracting sound in a manner that help to reduce extremes in a sound field in processing tank. Such perforations may be depressions and/or through apertures. In those embodiments in which a diffraction grating or other feature of an element constitutes a through aperture, such opening or perforations can additionally function to allow bubbles to escape from below a sonic diffuser system as described in further detail below. A single perforation or opening or the like may be used or an array of periodic or aperiodic perforations or openings may be used.

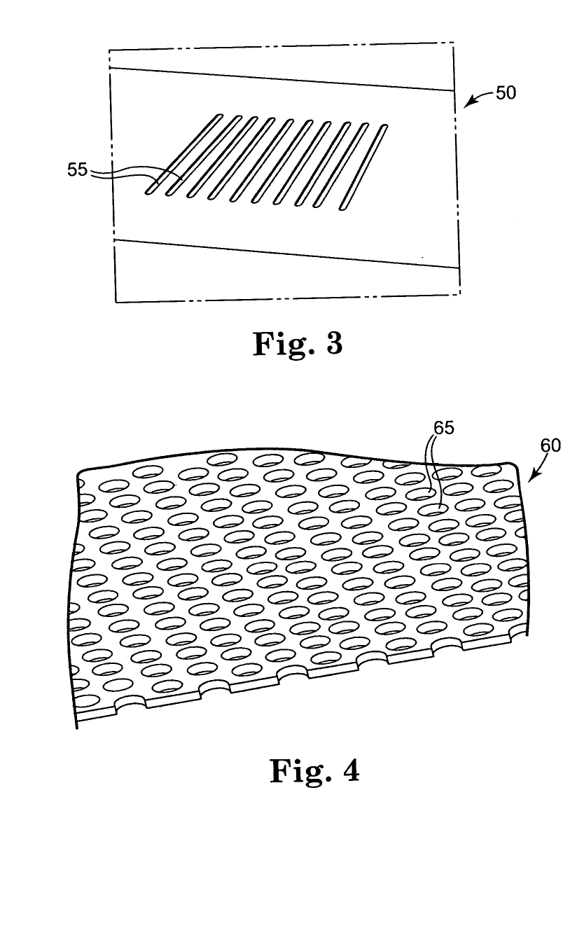

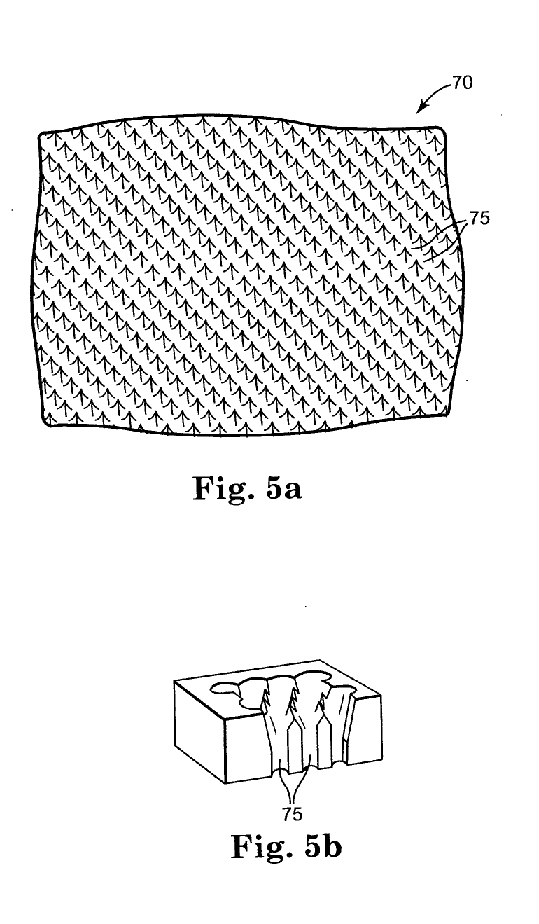

Representative examples of such sound diffusing systems incorporating diffraction features are shown in FIGS. 3-5. FIG. 3 shows a perspective view of a sound diffusing system 50 according to the present invention having a periodic array of openings 55. FIG. 4 shows a perspective view of another sound diffusing system 60 according to the present invention having a periodic array of openings/perforations 65. FIGS. 5a and 5b show a perspective view of another sound diffusing system 70 according to the present invention having a periodic array of openings/perforations 75.

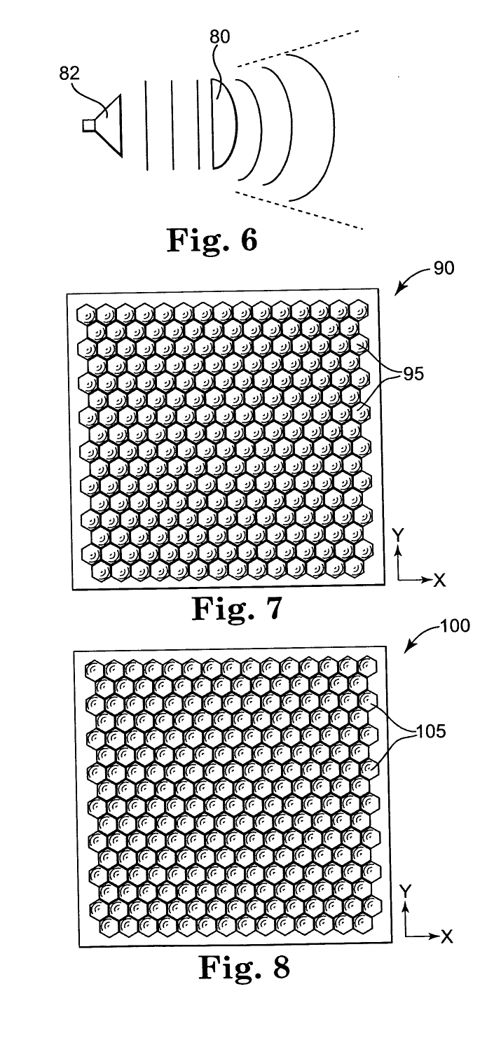

Acoustic energy may be diffused, modulated, or otherwise impacted when crossing a boundary between materials having different sonic velocities. Consequently, two or more materials may be used to form diffusing element(s) wherein the sonic velocities of such materials differ in a desired manner to provide diffusing function. The sonic velocity change may be abrupt, such as an interface between materials having different sonic velocities or may by a region where the sonic velocity changes such as a graded velocity region. For instance, FIG. 6 illustrates a diffusing element 80 in the form of a diverging lens can be formed from a plano-convex piece of HDPE and positioned with respect to megasonic energy source 82 in water. Given a speed of sound in water of 1500 m/s, in HDPE of 1900 m/s and the “Lens Makers Equation”:

$$\frac{1}{f} = ( n - 1 ) ( \frac{1}{{r}_{1}} )$$

where n is the ratio of speeds (1900/1500=1.27) and r₁ is the radius of curvature, a 1 cm diameter lens with a 1 cm radius of curvature would disperse the sound in a cone with a full angle of 16 degrees as illustrated in FIG. 6.

FIG. 7 shows a top plan view of an exemplary embodiment of a sound diffusing system 90 according to the present invention incorporating an array of convex hemispherical diffusing elements 95. FIG. 8 shows a top plan view of an exemplary embodiment of a sound diffusing system 100 according to the present invention incorporating an array of concave hemispherical diffusing elements 105. The arrays illustrated in FIGS. 7 and 8 each diffuse sound well in both the X and Y directions, but can have some field losses around the field periphery. That, is the field strength will tend to be stronger in the middle volume of the tank. Also, regular spacing of diffuser elements can promote the formation of maxima and minima due to interference of sound waves from different elements.

Preferably, sound diffusing systems of the present invention incorporate diffusing elements with aperiodic characteristics to help, for example, reduce the intensity of an interference pattern of acoustic energy established in a processing liquid. As one example of this approach, FIG. 9 shows a top plan view of a sound diffusing system 110 according to the present invention incorporating an array of hemispherical diffusing elements 115 in which the elements are of differing sizes and are arranged aperiodically, i.e., the center to center distance among elements is non-constant. This approach would reduce interference effects to a greater degree than the array shown in either FIG. 7 or 8, but may still have some field losses around the field periphery. Another approach for providing a sound diffusing system similar to that shown in FIG. 9 would be to randomly distribute diffusing elements 125 on a substrate 122 as shown in FIG. 10.

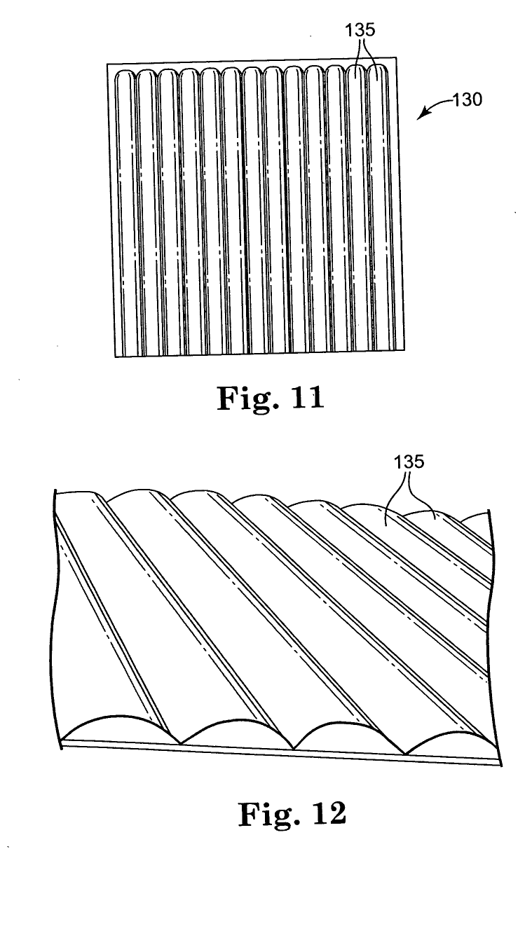

FIG. 11 shows a top, plan view of an exemplary sound diffusing system 130 of the present invention that provides lesser field losses around the sound field periphery. Sound diffusing system 130 incorporates an array of relatively long, cylinder-based, rib-like elements 135. FIG. 12 shows a perspective, cross-sectional view of the array of FIG. 11. Cylinder-based means that the cross-section of the element across a width fits partially or entirely into the cross-section of a cylinder. Note that the array of system 130 as shown in FIGS. 11 and 12 is periodic in that the centerline-to-centerline distance from one feature to another is constant. This array diffuses sound well in the X direction, and thus advantageously improves field uniformity at the periphery, but some interference effects may still be observed. Note that these elements are advantageously “full length” or “full width” in that each element 135 extends at least substantially from one end of the array to the other.

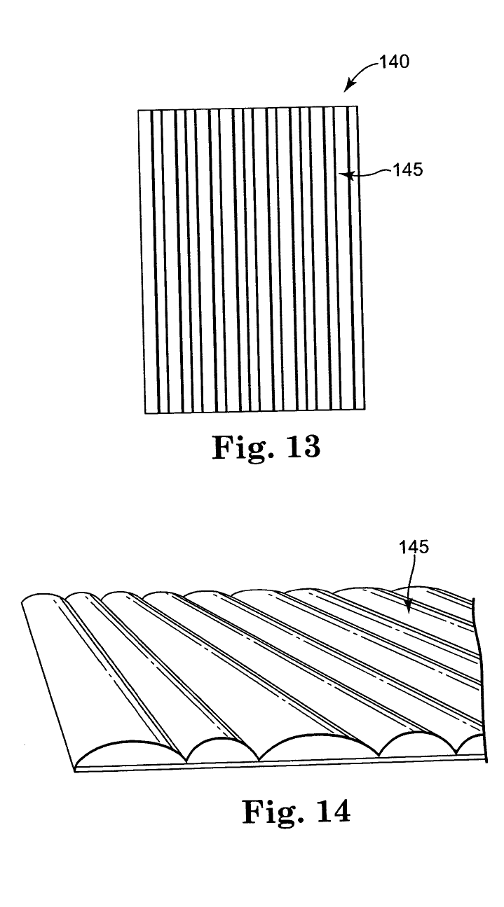

FIG. 13 shows a preferred sound diffusing system 140 according to the present invention that improves upon the system 130 in FIGS. 11 and 12 by using an aperiodic array of long, cylinder-based, rib-shaped elements 145 whose widths are non-constant. Specifically, the array includes a repeating pattern of ribs having five different widths. FIG. 14 shows a perspective, cross-sectional view of the array in FIG. 13.

The aperiodicity arises because the centerline to centerline distance from one element 145 to another is non-constant. With this aperiodic approach, the interference effects are dramatically dampened, and the field is highly uniform as between peripheral and middle regions. As an option, comparable aperiodicity could still be achieved by using cylinder-based elements with uniform widths that are nonetheless spaced apart nonuniformly.

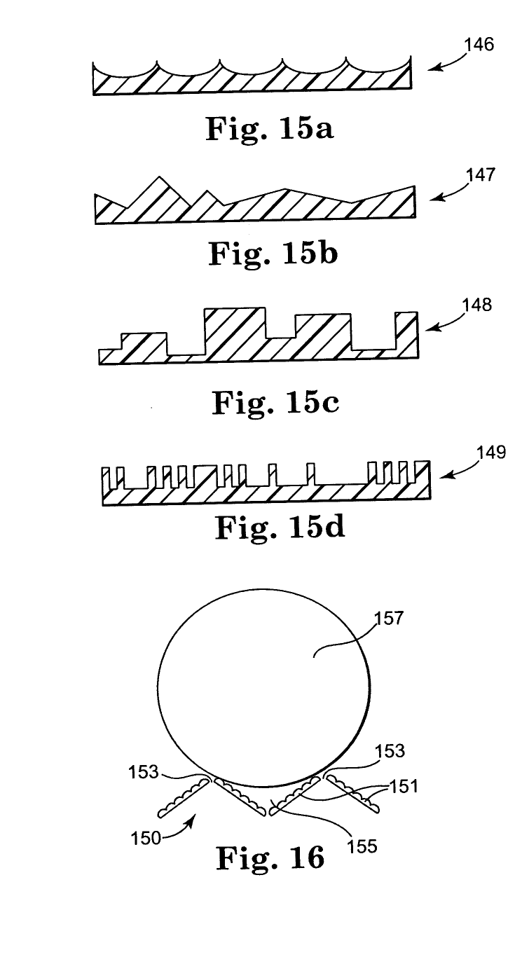

FIGS. 11-14 show diffusing elements that are cylinder-based protuberances. As an alternative, similar effects could also potentially be achieved by forming an array of linear or nonlinear ribs, slots, grooves, or the like in a suitable material such as shown in the cross-sectional views of sound diffusing systems 146, 147, 148, and 149 shown in FIGS. 15(a)-(d), respectively. However, diffusing elements with curvilinear output surfaces are preferred over those that have sharp corners, as the curvilinear surfaces diffuse sound waves more uniformly.

The Figures thus far show elements that are generally uniform in height, but vary in width. The Figures thus far also show that the height of the elements can also vary. In some embodiments, both the height and width can vary. The width and/or height, as the case may be, of the diffusing elements can vary over a wide range. Preferably, the height and/or width of each element should be about 50%, preferably about 100% of the shortest wavelength of sound being diffused. In actual practice, using cylinder-based elements whose width is 1 mm to 50 mm wide would be suitable.

Bubbles may have a tendency to get trapped beneath a diffuser array when the array is spaced apart from the tank floor or walls. Since bubbles act as a sound insulator, it is desirable to provide a way for the bubbles to escape. Sometimes, the array may be tilted sufficiently so that the bubbles will rise along the underside of the array and ultimately escape from under the higher edge of the array. In other instances one or more apertures or gaps may be formed in an array or among arrays to allow bubbles to escape. FIG. 16 shows a side view of a sound diffusing system 150 according to the present invention in which array sections 151 are arranged in a peaked fashion, like rooftops. The peaks have one or more apertures 153 to allow rising bubbles to escape, while the valley 155 between peaks fits nicely around the wafer(s) 157.

FIGS. 17-19 show an embodiment similar to the embodiment illustrated in FIG. 16. As shown, the acoustic diffuser device 160 generally comprises plural diffuser plates 161 supported and positioned relative to each other by a support frame 169. Each diffuser plate 161 includes multiple diffuser elements 165. Preferably, the support frame 169 cooperates with mounting structures 168 for mounting and positioning the acoustic diffuser device relative to a sound transducer (not shown) and a processing tank (not shown).

Any number of diffuser plates 161 may be used either with or without a support frame 169. In the illustrated embodiment, four diffuser plates 161 are positioned adjacent to each other and are angularly supported with respect to each other such that the diffuser device 160 includes two apexes or peaks. As shown, an apex of the diffuser device 160 corresponds to an edge of each adjacent diffuser plate 161. Also, as illustrated, the adjacent edges of adjacent diffuser plates 161 at an apex are slightly spaced apart such that an apex includes an opening or gap 163 between the adjacent diffuser plates 161. Such a gap 163 can allow bubbles that may become trapped under a diffuser plate 161 of the diffuser device 160 to escape. As such, the angle of the diffuser plates 161 may be chosen empirically so that entrapment of bubbles in minimized or avoided entirely. Wafer(s) 167 being processed fit nicely between the two peaks.

FIG. 1 shows an embodiment of a processing tank 10 in which window 26 is made from quartz. Recognizing that quartz reflects a significant portion of incident sound energy, it is optional to replace the quartz window 26 with a window of a different material that reflects less incident sound. As one example, one suitable substitute can be a window formed from a polymeric material that is inert with respect to the desired processing fluids. Windows made from one or more fluoropolymers would be especially useful, as fluoropolymers (such as thin fluoropolymer films) are highly transmissive with respect to sound energy and are chemically inert to a wide range of chemicals. Unlike quartz windows, which are generally rigid, polymeric windows may be rigid or flexible. The transmission through such materials would be high and highly uniform for several reasons such as (a) the thickness of the material can be highly uniform on the order of n/2 times the acoustic wavelength, so the phases of the reflections from the lower and upper surfaces would be almost exactly out of phase in the coupling liquid (little reflection), (b) the thickness of the material can be very small compared to the acoustic wavelength, so the phases of the reflections from the lower and upper surfaces would be almost exactly out of phase in the coupling liquid (little reflection), (c) the reflections from the upper and lower surfaces would also have a much lower absolute intensity, as the impedance of water is much closer to that of fluoropolymers and other polymers that of quartz, and (d) the material may be substantially transparent to megasonic sound.

As one example, a film such as about 0.5 mm thick PFA (American Durafilm pn 500LP) or other fluoropolymers and the like may be used for this application. These materials are generally mechanically strong, transparent to megasonic sound, and chemically resistant. For example, for many of these materials, the reflected sound can be less than about 5%.

The acoustic impedance of many polymers and water are closely matched, resulting in relatively little reflectance as sound crosses the water polymer and polymer water interfaces. The thickness of a polymer window is therefore limited primarily by internal absorption of sound within the window. Work with the diffusing lens array has demonstrated that sound can be transmitted acceptably through strong, rigid polymer plates on the order of 5 mm thick. Polymer window features can therefore be utilized as structural members of the tank design as, for example, in the minimum-volume, fast-draining and window-diffuser designs discussed below.

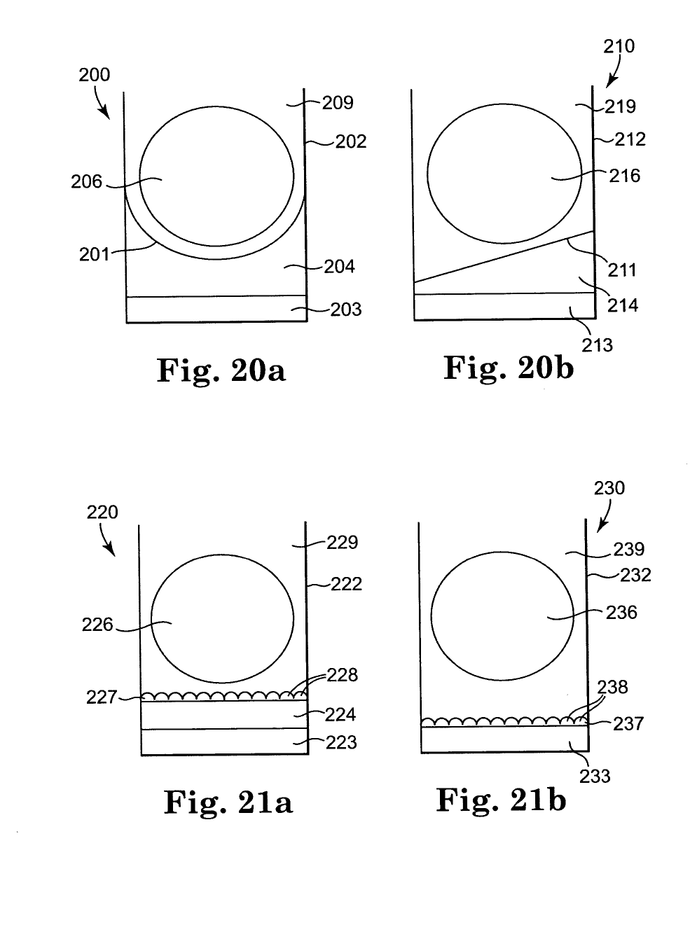

Such a window, film, or membrane could be used anywhere an acoustically transparent liquid barrier is needed. Additionally, the film can be shaped to minimize tank volume. Such a film can be shaped, topographically or otherwise, to act as an acoustic lens such as the acoustic lens described below. Possible designs for a minimum volume tank and a fast draining tank are shown in FIGS. 20(a) and (b), respectively.

The megasonic tank 200 shown in FIG. 20(a) includes a process chamber 209 defined in part by tank wall 202 and capable of having one or more wafer(s) 206 positioned therein for a treatment. Transducer 203 is coupled to the contents of process chamber 209 via coupling liquid 204. Polymer window 201 separates coupling liquid 204 from the contents of process chamber 209 and is designed for minimum tank volume.

The megasonic tank 210 shown in FIG. 20(b) includes a process chamber 219 defined in part by tank wall 212 and capable of having one or more wafer(s) 216 positioned therein for a treatment. Transducer 213 is coupled to the contents of process chamber 219 via coupling liquid 214. Polymer window 211 separates coupling liquid 214 from the contents of process chamber 219 and is designed for a fast draining tank.

In another aspect of the present invention, a non-planar film, an embossed film, or the like may be used as a diffuser. Such a film would then act to form topography at the interface between the coupling and processing liquids. The topography and acoustic sonic velocity differences between these liquids would combine to form diffusing elements. Also, the window and diffuser functions could be combined. The coupling and processing liquids could be separated by a diffuser system or array as described above, thus simplifying production of the tank structure. Also, a diffuser system or array in accordance with the present invention could be operatively attached to the crystal support plate of the acoustic energy source itself. As such, a coupling liquid may not be needed and a simplified structure would result. Alternatively, a diffuser system or array could be formed from the support plate if desired. Examples of a window-diffuser and a support-diffuser are shown in FIGS. 21(a) and (b), respectively.

The megasonic tank 220 shown in FIG. 21(a) includes a process chamber 229 defined in part by tank wall 222 and capable of having one or more wafer(s) 226 positioned therein for a treatment. Transducer 223 is coupled to the contents of process chamber 229 via coupling liquid 224. Window diffuser 227 separates coupling liquid 224 from the contents of process chamber 229 and includes multiple diffuser elements 228.

The megasonic tank 230 shown in FIG. 21(b) includes a process chamber 239 defined in part by tank wall 232 and capable of having one or more wafer(s) 236 positioned therein for a treatment. Transducer 233 is coupled to the contents of process chamber 239 via support diffuser 237, no coupling liquid is required. Support diffuser 237 includes multiple diffuser elements 238.

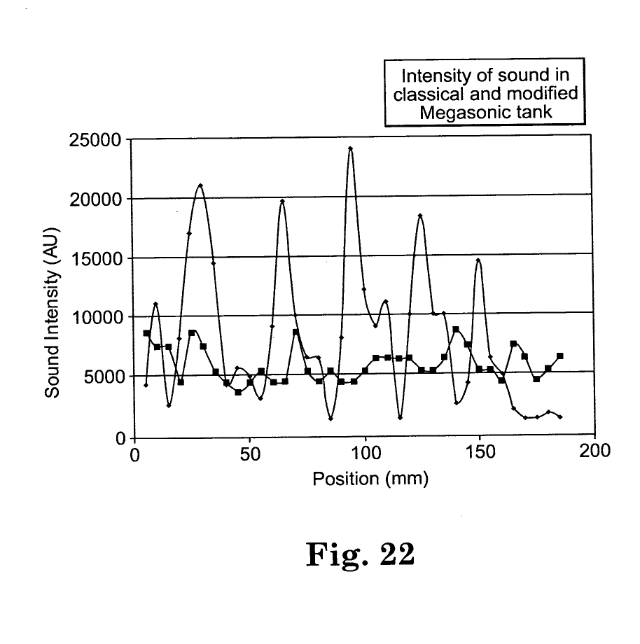

FIG. 22 shows a plot of sound intensity across a width of a particular megasonic processing tank with a quartz window at some point in time. The trace of the diamond shaped points shows sound intensity in the tank without an acoustic diffuser of the present invention. As shown, at this point in time, there are positions in the tank where sound intensity is relatively high and where sound intensity is relatively low in comparison. These high and low sound intensity regimes may relate to wafer damage regimes and under-processing regimes for wafers respectively. Such regimes are generally undesirable. In contrast, the trace of the square shaped data points of FIG. 22 shows sound intensity with respect to position in the processing tank at some point in time wherein the tank includes a diffusing device of the present invention. As illustrated, the sound intensity in the tank with a diffusing device of the present invention is generally more uniform and extreme high and low intensities are eliminated. In such a processing environment, such as for wafer cleaning or the like, more efficient and uniform cleaning may result with reduced or eliminated damage.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

1. An apparatus for immersion processing wafers, the apparatus comprising:
an immersion processing tank in which one or more wafers are positioned in a processing liquid during a treatment;
at least one sound source that is acoustically coupled to the processing liquid and that produces a sound field in the processing liquid contained in the processing tank during a treatment; and
a sound diffusing system comprising a plurality of sound diffusing elements positioned in a manner effective to diffuse sound energy transferred from the source to the processing liquid.

2. The apparatus of claim 1, wherein the plurality of sound diffusing elements form an array of integrally formed sound diffusing elements.

3. The apparatus of claim 1, wherein the plurality of sound diffusing elements comprise two or more sound diffusing elements having different sizes.

4. The apparatus of claim 3, wherein the sound diffusing system comprises an array of aperiodically arranged diffuser elements.

5. The apparatus of claim 1, wherein the plurality of sound diffusing elements form an array of sound diffusing elements, wherein the array comprises one or more gaps.

6. The apparatus of claim 1, wherein the plurality of sound diffusing elements form a plurality of arrays of sound diffusing elements, wherein the plurality of arrays comprise one or more gaps among the arrays.

7. The apparatus of claim 1, wherein at least one of the plurality of sound diffusing elements comprises diffraction grating.

8. The apparatus of claim 7, wherein the diffraction grating comprises one or more perforations.

9. The apparatus of claim 1, wherein at least one of the plurality of sound diffusing elements comprises a refracting element.

10. The apparatus of claim 1, wherein at least one of the plurality of sound diffusing elements comprises two or more materials, wherein the sonic velocities of such materials differ in a manner effective to diffuse sound energy in the processing liquid.

11. The apparatus of claim 1, further comprising:
a coupling liquid occupying a space between the one or more wafers and the at least one sound source; and
an acoustic window positioned between and separating the processing liquid and the coupling liquid, wherein the sound diffusing system is positioned in the coupling liquid, between the sound source and the acoustic window.

12. The apparatus of claim 1, further comprising:
a coupling liquid occupying a space between the one or more wafers and the at least one sound source; and
an acoustic window positioned between and separating the processing liquid and the coupling liquid, wherein the sound diffusing system is positioned in the processing liquid, between the acoustic window and the one or more wafers.

13. The apparatus of claim 1, further comprising:
a coupling liquid occupying a space between the one or more wafers and the at least one sound source; and
an acoustic window positioned between and separating the processing liquid and the coupling liquid, wherein the acoustic window is made from material comprising polymeric material.

14. The apparatus of claim 1, further comprising:
a coupling liquid occupying a space between the one or more wafers and the at least one sound source; and
an acoustic window positioned between and separating the processing liquid and the coupling liquid, wherein the sound diffusing system forms at least part of the acoustic window.

15. The apparatus of claim 1, wherein the at least one sound source further comprises a first surface and the sound diffusing system further comprises a second surface, wherein the first surface is operatively attached to the second surface.

16. The apparatus of claim 1, wherein the at least one sound source further comprises a first surface and wherein the sound diffusing system is formed from the first surface.

17. The apparatus of claim 1, wherein the sound diffusing system comprises a plurality of angularly oriented sound diffusing members, each sound diffusing member including a plurality of sound diffusing elements.

18. A method of providing a sound field in a processing liquid contained in an immersion processing tank, the method comprising the steps of:
providing a sound field in the processing liquid; and
directionally phase modulating the sound field by using a sound diffusing system including a plurality of sound diffusing elements.

19. A method of providing a sound field in a processing liquid contained in an immersion processing tank, the method comprising the steps of:
determining information indicative of a sound field variation in the processing liquid; and
using said information to provide a sonic diffuser system to be used to diffuse sound energy in the processing liquid during a wafer treatment process.

20. An apparatus for immersion processing wafers, the apparatus comprising:
an immersion processing tank in which one or more wafers are positioned in a processing liquid during a treatment;
at least one sound source that produces a sound field in the processing liquid contained in the processing tank; and
a sound diffusing system comprising at least one directionally phase modulating element positioned in a manner effective to reduce interference of sound energy in the processing liquid.
